(19) United States
(12) Patent Application Publication
(10) Pub. No.: US 2004/0212067 A1
(43) Pub. Date: Oct. 28, 2004

(54) Multi-chips stacked package

(75) Inventor: Meng-Jen Wang, Pingtung City (TW)

Correspondence Address: BACON & THOMAS, PLLC, 625 SLATERS LANE, FOURTH FLOOR, ALEXANDRIA, VA, 22314

(73) Assignee: Advanced Semiconductor Engineering, Inc., Kaoshiung (TW)

(21) Appl. No.: 10/820,800

(22) Filed: Apr. 9, 2004

(30) Foreign Application Priority Data
Apr. 25, 2003 (TW) 092109653

(51) Int. Cl. H01L 23/02

(52) U.S. Cl. 257/686

(57) ABSTRACT

A multi-chips stacked package at least comprises a substrate, an upper chip, a lower chip, a reinforced bump and a plurality of conductive bumps. The upper chip is flip-chip bonded to the upper surface of the substrate; and the lower chip is accommodated in the opening and flip-chip bonded to the upper chip. The reinforced bump is mounted onto the active surface of the upper chip and connected to the substrate so as to enhance the attachment of the upper chip to the substrate. In such a manner, the reinforced bump will restrain the thermal deformation of the substrate and the upper chip so as to prevent the electrically conductive bumps connecting the upper chip and the substrate from being damaged.

### BACKGROUND OF THE INVENTION

1. Field of Invention

This invention relates to a multi-chips stacked package. More particularly, the present invention is related to a multi-chips stacked package with at least a reinforced bump interposed between the chip and the substrate so as to prevent the electrically conductive bumps connecting the substrate and the chip from being damaged.

2. Related Art

As we know, in the semiconductor industries, the manufacture of semiconductors mainly comprises the manufacture of wafers and the assembly of integrated circuits devices. Therein, the integrated circuits (ICs) devices are completely formed by the processes of forming integrated circuits devices on the semiconductor wafers, sawing the wafers into individual integrated circuits devices, placing the individual integrated circuits devices on the substrates, electrically connecting the integrated circuits devices to the substrates and encapsulating the integrated circuits devices and substrates to form a plurality of assembly packages. Due to the encapsulation covering the integrated circuits devices, the integrated circuits devices are able to be protected from the damp entering. In addition, the assembly packages may further provide external terminals for connecting to printed circuit board (PCB).

However, recently, integrated circuits packaging technology is becoming a limiting factor for the development in packaging integrated circuits devices of higher performance. Semiconductor package designers are struggling to keep pace with the increase in pin count, size limitations, low profile, and other evolving requirements for packaging and mounting integrated circuits.

Due to the assembly package in miniature and the integrated circuits operation in high frequency, MCM (multi-chips module) packages are commonly used in said assembly packages and electronic devices. Usually, said MCM package mainly comprises at least two chips encapsulated therein, for example a processor unit, a memory unit and related logic units, so as to upgrade the electrical performance of said assembly package. In addition, the electrical paths between the chips in said MCM package are short so as to reduce the signal delay and save the reading and writing time.

Per the above-mentioned, a multi-chips stacked package is provided, as shown in FIG. 1, as a standard and common design. Referring to FIG. 1, it is characterized that an upper chip 110 is flipped over and disposed above an opening 122 passing through the upper surface 124 and the lower surface 126 of the substrate 120, and electrically connected to the substrate 120 through electrically conductive bumps 150; and a lower chip 130 is accommodated in the opening 122 and electrically connected to the upper chip through another electrically conductive bumps 160. Generally speaking, the upper chip 110 and the lower chip 130 are a memory chip and a logic chip respectively. In such a manner, the electrical signals are able to be integrated in the package and then are transmitted to external devices through solder balls 128 attached to the lower surface 126 of the substrate 120. Accordingly, the size of said multi-chips stacked package is reduced and the transmission paths of the electrical signals are shortened. Namely, the signal delay is reduced and the electrical performance of said multi-chips stacked package is upgraded.

As mentioned above and per the conventional invention as shown in FIG. 1, the upper chip 110 is electrically connected to the substrate 120 through electrically conductive bumps 150. Generally, the organic substrate, for example Bismaleimide-Triazine (BT), is taken as the substrate 120 to carry the upper chip 110 wherein the coefficient of thermal expansion of the substrate 120 is about 16*10⁻⁶ ppm/° C. and the coefficient of thermal expansion of the upper chip 110 is about 4*10⁻⁶ ppm/° C. Accordingly, the coefficient of thermal expansion of the upper chip 110 is much smaller than that of the substrate 120 and the electrically conductive bumps 150 connecting the upper chip 110 and the substrate 120 are usually damaged due to the CTE mismatch of the substrate 120 with the upper chip 110. Notwithstanding there is an underfill 130 interposed between the upper chip 110 and the substrate 120 and filled into the space between the upper chip 110 and the substrate 120 to lower the stress at the electrically conductive bumps 150, the bumps 150 are still damaged due to the much difference of the coefficient of thermal expansion of the substrate 120 from that of the upper chip 110.

Therefore, providing another multi-chips stacked package to solve the mentioned-above disadvantages is the most important task in this invention.

### SUMMARY OF THE INVENTION

In view of the above-mentioned problems, an objective of this invention is to provide a multi-chips stacked package which is characterized in that the electrically conductive bumps provided in the multi-chips stacked package is able to be prevented from being damaged due to a reinforced bump connecting the chip to the substrate.

To achieve the above-mentioned objective, a multi-chips stacked package is provided, wherein the multi-chips stacked package mainly comprises a substrate having an opening, an upper chip, a lower chip, a reinforced bump and a plurality of electrically conductive bumps. Therein, the upper chip is flipped over and disposed above the opening, and the active surface of the upper chip is attached to the upper surface of the substrate through the electrically conductive bumps; and the lower chip is accommodated in the opening and connected to the upper chip by another electrically conductive bumps. Moreover, the reinforced bump is disposed on the substrate and connected to the upper chip so as to enhance the attachment of the upper chip to the substrate. Accordingly, the reinforced bump can lower the stress at the electrically conductive bumps connecting the upper chip and the substrate and prevent the electrically conductive bumps from being damaged.

In summary, this invention is related to a multi-chips stacked package utilizing a reinforced bump interposed between the upper chip and the substrate to enhance the attachment of the upper chip to the substrate and prevent the electrically conductive bumps connecting the upper chip and the substrate from being damaged. Namely, the stress at the electrically conductive bumps between the upper chip and the substrate will be lowered, and the substrate will be prevented from being warped so that the reliability of the multi-chips stacked package will be upgraded. Besides, the reinforced bump can be a dummy bump, such as an epoxy bump. Moreover, the reinforced bump can be an eutectic bump, wherein the ratio of tin and lead is 63:37 or 5:95. However, the reinforced bump is not electrically connected to the substrate.

### BRIEF DESCRIPTION OF THE DRAWINGS

The invention will become more fully understood from the detailed description given herein below illustrations only, and thus are not limitative of the present invention, and wherein:

FIG. 1 is a cross-sectional view of the conventional multi-chips stacked package;

FIG. 2 is a cross-sectional view of a multi-chips stacked package according to the preferred embodiment;

FIG. 3 is a cross-sectional view of a multi-chips stacked package according to another preferred embodiment;

FIG. 4 is a top view of the upper chip of the multi-chips stacked package according to the preferred embodiment as shown in FIG. 2;

FIG. 5 is a top view of the upper chip of the multi-chips stacked package according to the preferred embodiment as shown in FIG. 3; and

FIG. 6 is a cross-sectional view of a multi-chips stacked package according to another preferred embodiment.

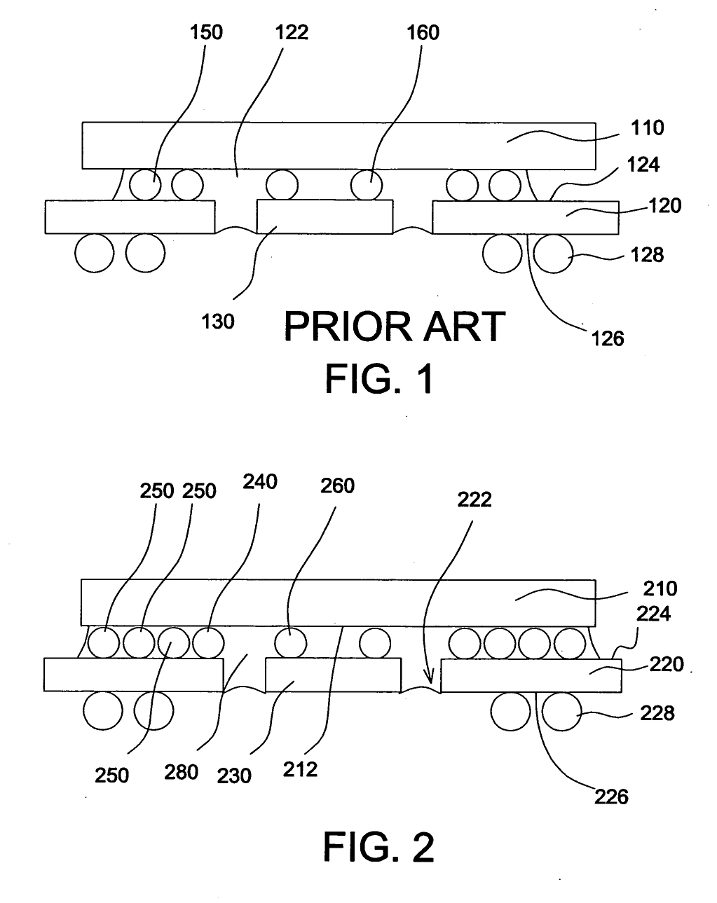

### DETAILED DESCRIPTION OF THE INVENTION

The multi-chips stacked package according to the preferred embodiments of this invention will be described herein below with reference to the accompanying drawings, wherein the same reference numbers refer to the same elements.

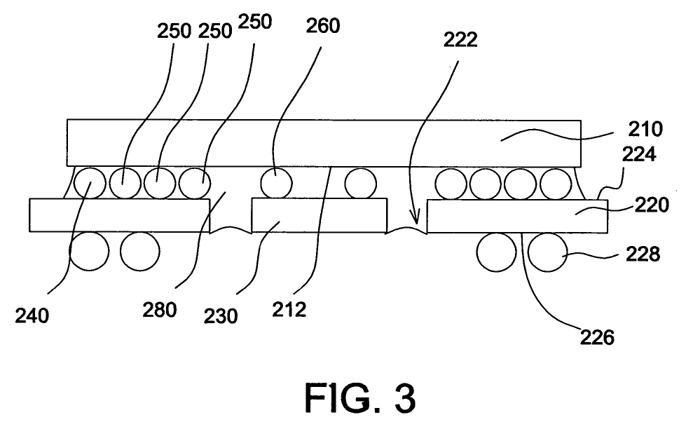

In accordance with preferred embodiments as shown in FIG. 2 and FIG. 3, there are provided multi-chips stacked packages respectively. Referring to FIG. 2, the multi-chips stacked package mainly comprises an upper chip 210, a substrate 220 having an opening 222, a lower chip 230, a reinforced bump 240, a plurality of first electrically conductive bumps 250 and a plurality of second electrically conductive bumps 260. Therein, the substrate 220 further has an upper surface 224 and a lower surface 226, and the opening 222 passes through the upper surface 224 and the lower surface 226. Besides, the upper chip 210 is flipped over and attached to the upper surface 224 of the substrate 220 via a plurality of first electrically conductive bumps 250 so as to cover the opening 222 of the substrate 220. Moreover, the lower chip 230 is accommodated in the opening 222 and attached to the upper chip 210 via a plurality of second electrically conductive bumps 260. Meanwhile, the reinforced bump 240 is interposed between the upper surface 224 of the substrate 220 and the upper chip 210, and connects the substrate 220 and the upper chip 210 so as to enhance the attachment of the upper chip 210 to the substrate 220.

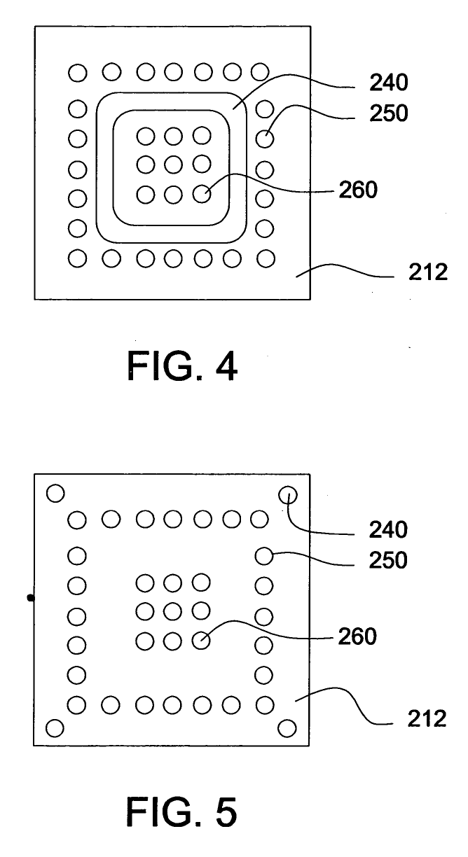

As mentioned above, when the thickness or the size of the upper chip 210 is larger than usual one, the first electrically conductive bump 250 located on the active surface 212 of the upper chip 210 and close to the center of the upper chip 210 is easily damaged. Accordingly, the reinforced bump 240 disposed on the active surface 212 and close to the perimeter of the opening 222 as shown in FIG. 2 is able to prevent the first electrically conductive bumps 250 from being damaged. When the reinforced bump 240 is formed in a ring-like shape and located close to the perimeter of the opening 222 as shown in FIG. 4, the attachment of the upper chip 210 to the substrate 220 will be enhanced. On the contrast, when the thickness or the size of the upper chip 210 is smaller than usual one, the first electrically conductive bump 250 located at the periphery of the active surface 212 of the upper chip 210 and far away the center of the upper chip 210 and the perimeter of the opening 222 is easily damaged. Accordingly, the reinforced bump 240 disposed at the periphery of the active surface 212 and outside the first electrically conductive bump 250 as shown in FIG. 3 is able to prevent the first electrically conductive bumps 250 from being damaged. Preferably, the reinforced bump 240 can be located at the corners of the active surface 212 of the upper chip 210 as shown in FIG. 5. Similarly, the reinforced bump 240 can be a ring-like bump at the peripheral of the active surface 212.

Moreover, as shown in FIG. 2 and FIG. 3, there is an underfill 280 filled into the opening 222 to cover the first electrically conductive bumps 250 and the second electrically conductive bumps 260 so as to prevent the first electrically conductive bumps 250 connecting the substrate 220 and the upper chip 210 from being damaged due to CTE mismatch. When the back surface 232 of the lower chip 230 is exposed out of the underfill 280 and a portion of the active surface 212 of the upper chip 210 is not covered by the underfill 280, the thermal performance of the package will be enhanced. On the contrast, when the active surface 212 of the upper chip 210 is entirely covered by the underfill 280, the attachment of the upper chip 210 to the substrate 220 will be enhanced. In addition, there are a plurality of solder balls 228 attached on the lower surface 226 of the substrate 220 to be regarded as electrical terminals to transmit the electrical signals from the upper chip 210 and the lower chip 230 to external electronic devices. It should be noted that the substrate 220 can be replaced by a lead frame, such as lead-less lead frame.

As we know, when the reinforced bump 240 is made of high-lead solder, wherein the ratio of lead and tin is 95:5 or 80:20, the reinforced bump 240 has a larger boding strength to connect the substrate 220 and the upper chip 210 so as to restrain the deformation of the substrate 220 and the upper chip due to CTE mismatch.

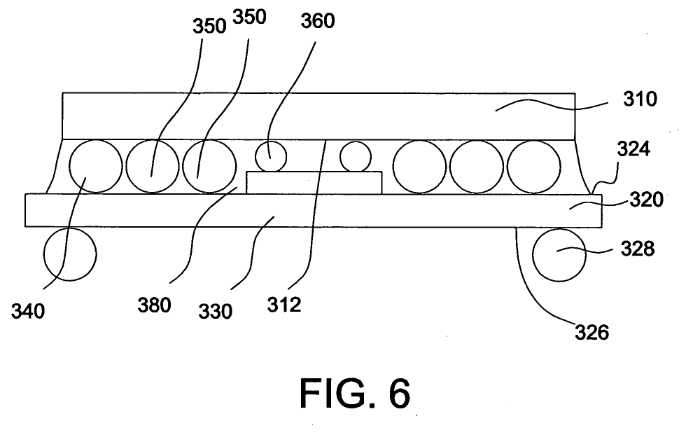

Moreover, when the substrate 320 has no opening therein, the lower chip 330 will be placed above the upper surface 324 of the substrate 320 as shown in FIG. 6. Accordingly, the height of the electrically conductive bump 350 connecting the upper chip 310 to the substrate 320 is larger than that of the electrically conductive bump 360 connecting the lower chip 330 to the upper chip 310 and substantially equal to the reinforced bump 340 interposed between the substrate 320 and the upper chip 310.

Although the invention has been described in considerable detail with reference to certain preferred embodiments, it will be appreciated and understood that various changes and modifications may be made without departing from the spirit and scope of the invention as defined in the appended claims.

What is claimed is:

1. A multi-chips stacked package, comprising:
a substrate having an upper surface, a lower surface and an opening passing through the upper surface and the lower surface;
an upper chip having a first active surface and a first back surface, wherein the upper chip is flipped over and attached to the upper surface of the substrate via a plurality of first electrically conductive bumps;
a lower chip accommodated in the opening and electrically connected to the first active surface of the upper chip through a plurality of second electrically conductive bumps; and
a reinforced bump interposed between the substrate and the upper chip.

2. The multi-chips stacked package of claim 1, further comprising an underfill filled into the opening.

3. The multi-chips stacked package of claim 2, wherein the underfill covers the first electrically conductive bumps and the second electrically conductive bumps.

4. The multi-chips stacked package of claim 1, wherein the upper chip covers the opening.

5. The multi-chips stacked package of claim 1, wherein the reinforced bump is located at a corner of the active surface of the upper chip.

6. The multi-chips stacked package of claim 1, wherein the reinforced bump is located at a periphery of the first active surface of the upper chip.

7. The multi-chips stacked package of claim 1, wherein the reinforced bump is close to the perimeter of the opening.

8. The multi-chips stacked package of claim 1, wherein the reinforced bump is a ring-like bump.

9. The multi-chips stacked package of claim 1, wherein the reinforced bump is a bar-like bump.

10. The multi-chips stacked package of claim 2, wherein the underfill covers the reinforced bump.

11. The multi-chips stacked package of claim 1, wherein the reinforced bump is a solder bump.

12. The multi-chips stacked package of claim 11, wherein the material of the reinforced bump comprises lead and tin.

13. The multi-chips stacked package of claim 12, wherein the ratio of the lead and the tin is 95:5.

14. The multi-chips stacked package of claim 2, wherein the lower chip has a second back surface exposing out of the underfill.

15. The multi-chips stacked package of claim 1, further comprising a plurality of solder balls formed on the lower surface of the substrate.

16. The multi-chips stacked package of claim 1, wherein the reinforced bump is made of epoxy.

17. The multi-chips stacked package of claim 1, wherein the upper chip is larger than the lower chip in size.

18. The multi-chips stacked package of claim 2, wherein the underfill covers a portion of the first active surface of the upper chip.

19. The multi-chips stacked package of claim 2, wherein the underfill entirely covers the first active surface of the upper chip.

20. The multi-chips stacked package of claim 2, wherein the underfill covers a portion of the upper surface of the substrate.

21. A multi-chips stacked package, comprising:
a substrate having an upper surface and a lower surface;
an upper chip having a first active surface and a first back surface, wherein the upper chip is flipped over and attached to the upper surface of the substrate via a plurality of first electrically conductive bumps;
a lower chip interposed between the upper surface of the substrate and the first active surface of the upper chip and electrically connected to the first active surface of the upper chip through a plurality of second electrically conductive bumps; and
a reinforced bump interposed between the upper surface of the substrate and the first active surface of the upper chip.

22. The multi-chips stacked package of claim 21, wherein each of the first electrically conductive bumps is larger than each of the second electrically conductive bumps in height.

23. The multi-chips stacked package of claim 21, wherein each of the first electrically conductive bumps is substantially equal to the reinforced bump in height.
